(19) United States
(12) Patent Application Publication
(10) Pub. No.: US 2024/0153774 A1
(43) Pub. Date: May 9, 2024

(54) MULTIPROCESS SUBSTRATE TREATMENT FOR ENHANCED SUBSTRATE DOPING

(71) Applicant: Applied Materials, Inc., Santa Clara, CA (US)

(72) Inventors: Christopher R. Hatem, Seabrook, NH (US); Michael Noel Kennedy, Boston, MA (US); Joseph C. Olson, Beverly, MA (US); Edmund G. Seebauer, Urbana, IL (US)

(73) Assignee: Applied Materials, Inc., Santa Clara, CA (US)

(21) Appl. No.: 17/980,900

(22) Filed: Nov. 4, 2022

(51) Int. Cl. H01L 21/225; H01J 37/32; H01L 21/265

(52) U.S. Cl. CPC H01L 21/2251; H01J 37/32357; H01J 37/32412; H01L 21/26513; H01J 2237/332; H01J 2237/335

(57) ABSTRACT

A method of doping a substrate may include exposing a substrate surface of the semiconductor substrate to a plasma clean, performing a deposition of a dopant layer on the substrate surface using a plasma source, after the plasma clean, the dopant layer comprising a dopant element; and exposing the substrate to an implant process when the dopant layer is disposed on the substrate surface, wherein the implant process introduces an ion species comprising the dopant element into the substrate, wherein the substrate is maintained under vacuum over a process duration spanning the plasma clean, the deposition of the dopant layer, and the implant process, and wherein at least a portion of the dopant layer is implanted into the substrate during the implant process.

### FIELD

The present embodiments relate to methods of doping a substrate, and more particularly methods of three-dimensional doping.

### BACKGROUND

As semiconductor devices such as logic and memory devices continue to scale to smaller dimensions, the use of conventional processing and materials to fabricate semiconductor devices is increasingly problematic. In one example, new approaches for doping semiconductor structures are being investigated to supplant ion implantation. For example, in future technology generations, transistors may be formed of three-dimensional structures, such as horizontal gate all around structures (HGAA) where active regions are formed using so-called nanowires. Doping of such advanced devices may entail ion implantation, where dopant ions are introduced into the substrate, which process may be followed by annealing to activation dopants. Among other challenges are the need to achieve a very high dopant activation while at the same time maintaining a shallow junction depth of the dopants that is compatible with the dimensions of the advanced devices.

With respect to these and other considerations the present disclosure has been provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In one embodiment, a method of doping a substrate may include exposing a substrate surface of the semiconductor substrate to a plasma clean, and performing a deposition of a dopant layer on the substrate surface using a plasma source, after the plasma clean, where the dopant layer includes a dopant element. The method may include exposing the substrate to an implant process when the dopant layer is disposed on the substrate surface, wherein the implant process introduces an ion species comprising the dopant element into the substrate. The semiconductor substrate may be maintained under vacuum over a process duration that spans the plasma clean, the deposition of the dopant layer, and the implant process, wherein at least a portion of the dopant layer is implanted into the substrate during the implant process.

In another embodiment, a method of doping a substrate a method of doping a substrate may include providing a monocrystalline semiconductor material on a surface of the substrate, and exposing the surface of the substrate to a plasma clean, wherein a native oxide is removed from the surface of the substrate. The method may include performing a deposition of a dopant layer on the substrate surface using a plasma source, after the plasma clean, the dopant layer comprising a dopant element. The method may also include exposing the substrate to an implant process when the dopant layer is disposed on the surface of the substrate, wherein the implant process introduces an ion species comprising the dopant element into the substrate. The substrate may be maintained under vacuum over a process duration spanning the plasma clean, the deposition of the dopant layer, and the implant process, wherein at least a portion of the dopant layer is implanted into the substrate during the implant process.

In a further embodiment, a method of doping a semiconductor substrate may include providing the semiconductor substrate in a beamline ion implanter, and exposing the surface of the semiconductor to a plasma clean. The method may include performing a deposition of a dopant layer on the substrate surface using a plasma source, after the plasma clean, where the dopant layer includes a dopant element. The method may include exposing the semiconductor substrate to an implant process when the dopant layer is disposed on the substrate surface, wherein the implant process introduces an ion species comprising the dopant element into the semiconductor substrate. The semiconductor substrate may be maintained in the beamline ion implanter under vacuum over a process duration spanning the plasma clean, the deposition of the dopant layer, and the implant process, wherein at least a portion of the dopant layer is driven into the semiconductor substrate during the implant process.

### BRIEF DESCRIPTION OF THE DRAWINGS

FIGS. 1A-1E illustrate exemplary operations involved in doping a substrate according to embodiments of the disclosure;

FIGS. 2A-2B illustrate exemplary dopant profiles for substrates processed according to the present embodiments, for boron and phosphorous, respectively;

FIG. 3 illustrates an exemplary ion implanter according to some embodiments of the disclosure; and

FIG. 4 depicts an exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

In the present embodiments, the present inventors have identified novel approaches to promote improved doping into a semiconductor structure, such as a monocrystalline semiconductor material. In various non-limiting embodiments, suitable semiconductor structures include silicon, silicon-germanium alloys (SiGe), or silicon-phosphorous alloys.

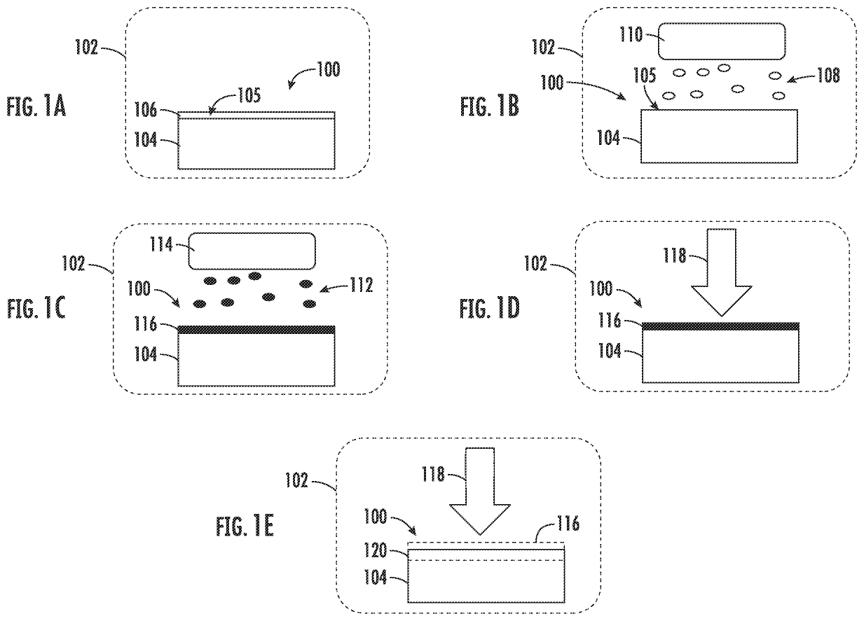

FIGS. 1A-1E illustrate exemplary operations involved in doping a substrate according to embodiments of the disclosure. Turning in particular to FIG. 1A, there is shown a first instance where a semiconductor substrate 100 is provided in an ion implantation apparatus 102 or system. The ion implantation apparatus 102 may represent a beamline ion implanter in some non-limiting embodiments, or other apparatus suitable to perform ion-implantation. The ion implantation apparatus 102 may include one or more chambers or locations that house the semiconductor substrate 100 during various processes to be performed.

While the semiconductor substrate 100 is located within the ion implantation apparatus 102, it may be understood that high vacuum conditions are maintained. For example, during ion implantation of the semiconductor substrate 100, vacuum levels of less than 10-3 torr may be maintained in the end station housing the semiconductor substrate 100. During other processing operations, such as plasma-based operations, the vacuum levels of less than 10-1 torr may be maintained, while during idle periods, vacuum levels of less than 10-4 torr may be maintained according to non-limiting embodiments of the disclosure. Furthermore, exposure to ambient gaseous species outside of the ion implantation apparatus 102 may be precluded during the operations shown in FIG. 1A-FIG. 1E.

At the stage represented in FIG. 1A, the semiconductor substrate 100 may be placed into the ion implantation apparatus, after having received processing through multiple operations in order to synthesize devices, such as logic devices, memory devices, or other devices to receive implantation processing for the purposes of doping. In the example shown, the semiconductor substrate 100 includes a substrate base 104, formed of monocrystalline semiconductor material. In some embodiments, the semiconductor substrate 100 may also include a native oxide layer 106, disposed on the surface 105. As depicted in FIG. 1A the substrate base 104 and native oxide layer 106 may represent any suitable portion of a semiconductor substrate, including patterned regions of a semiconductor device, such as source/drain regions, according to various embodiments of the disclosure. The native oxide layer 106 may represent that layer forming after processing to remove any other materials from the surface of the substrate base 104. The formation of native oxide on silicon and like semiconductors in well-known and will not be discussed in detail herein. However, even when monocrystalline silicon is processed to remove any oxide or other non-silicon material from an outer surface, a native oxide may tend to form upon exposure to oxygen-containing (including water vapor) atmosphere, such as the ambient outside of a vacuum processing tool. Moreover, native oxide tends to be self-limiting in thickness, such that the thickness of the native oxide layer 106 may be assumed to be no more than 4 nm-8 nm in some non-limiting embodiments.

Turning to FIG. 1B, there is shown a subsequent instance where the surface 105 of semiconductor substrate 100 is exposed to a plasma clean operation. Initially, the surface 105 may be covered with up to several nm of native oxide, represented by the native oxide layer 106. In some embodiments, the plasma clean operation may employ a plasma source 110 that is located the ion implantation apparatus 102. The plasma source 110 may represent any suitable apparatus to generate a plasma, and in some instances may represent a radical source. In any case, the plasma source 110 may generate cleaning species 108, which species may represent a combination of ions and neutrals, including radicals.

In the case of the cleaning species 108 including ions, during the plasma clean operation, the energy of the ions may be maintained below 100 eV, such as in the range of several eV to 30 eV in some non-limiting embodiments. In some embodiments, the cleaning species 108 may represent known reactive species that tend to chemically react to etch the native oxide layer 106, even when the energy of such reactive species is on the order of several eV. In various embodiments, the cleaning species 108 may selectively etch the native oxide layer 106 with respect to the substrate base 104. As such, the native oxide layer 106 may be removed from the substrate base 104 with little or no etching of the substrate base 104, and little or no damage to the substrate base 104, due to the low energy of the cleaning species 108.

According to some embodiments, the plasma clean operation of FIG. 1B may be accomplished by generating hydrogen species in a plasma chamber of plasma source 110, and directing the hydrogen species to the surface 105 when the substrate is at a cleaning temperature between room temperature and 100° C. The hydrogen species may be generated by providing an H₂ gas for example to a plasma chamber. As such, the surface 105 may represent a ‘clean’ semiconductor surface that presents silicon species to the ambient within ion implantation apparatus 102, with minimal or no foreign species such as oxygen or carbon on the surface 105.

In some embodiments, the plasma clean operation may involve a plurality of sub-operations. For example, a first plasma clean sub-operation may be performed by generating a cleaning species from a plasma source that reacts to remove a portion of or all of the native oxide layer 106. This cleaning species may be a species different from hydrogen, for example. A second plasma clean sub-operation may then involve generating a hydrogen plasma and directing the hydrogen species to the surface 105 to remove any residual oxide, carbon, or other contaminant and to terminate the surface 105 with a hydrogen passivation. In other examples, just hydrogen species may be used to perform native oxide removal and hydrogen termination. In any case, the plasma clean operation may be completed by generating a hydrogen plasma and directing hydrogen species to the surface 105 to form a hydrogen passivation on the surface 105. Said differently, the plasma clean operation of FIG. 1B may considered to involve the sub-operations of native oxide removal followed by hydrogen termination of the surface 105. Likewise, in some embodiments, the “cleaning species” 108 may represent more than one species, such as a separate non-hydrogen species to etch the native oxide layer 106, as well as a hydrogen species to hydrogen-passivate the surface 105 after native oxide layer 106 removal.

Turning now to FIG. 1C, there is shown an instance, subsequent to the instance of FIG. 1B, where a deposition of a dopant layer 116 is performed on the surface 105 of the semiconductor substrate 100. The deposition may be performed by a plasma source 114, located in the ion implantation apparatus 102. In some embodiments, the plasma source 114 may or may not be the same source as plasma source 110. The deposition of the dopant layer 116 may be performed by generating a dopant species that includes a dopant element. The dopant species 112 may be an ion or radical, and may be directed to the surface 105 when the semiconductor substrate 100 is at a substrate temperature of between room temperature and −100° C. according to some non-limiting embodiments. The dopant species 112 may be formed by providing a precursor gas that is a boron-containing species or a phosphorous-containing species, such B₂F₆, as BF₃ or PF₃ to the plasma source 110, which gas is ionized and decomposed to form active species that are represented by dopant species 112. When condensing to form the dopant layer 116, the dopant species 112 may further decompose to leave behind predominantly a dopant element such as boron or phosphorous to form the dopant layer 116.

In various non-limiting embodiments of the disclosure, the dopant species 112 may be provided to the surface 105 at an energy that may vary from several eV to 100 eV. As such, the energy of the dopant species 112 may be such that little sputtering takes place during deposition of the dopant species 112, as well as little damage to region at or near the surface 105, including implantation of the dopant species 112, and related collision cascades within the substrate base 104.

In accordance with various embodiments, the dopant layer 116 may have a thickness in the range of 1 nm to 7 nm at the processing stage represented in FIG. 1C, after deposition is completed. As discussed further below, this thickness may be tailored according to various considerations, including the targeted dopant concentration in the substrate base 104 near the surface 105, the targeted contact resistance of a device to be formed, the targeted junction depth of a source/drain junction to be formed, and other factors.

Turning now to FIG. 1D, there is shown a subsequent instance where the semiconductor substrate 100 is exposed to an implant process on the surface 105 when the dopant layer is disposed on the substrate surface, when the dopant layer is disposed in the ion implantation apparatus 102. In so doing, the implant process introduces an ion species 118 comprising the dopant element into the semiconductor substrate 100, an in particular, into the substrate base 104. Note that ion species 118 may be provided as an ion beam in a beamline ion implanter for example. In some examples the ion species 118 may be provided as an analyzed ion beam that contains the same dopant element as the dopant element of dopant layer 116. The analyzed ion beam may thus have a well-defined ion energy and composition for the ion species 118.

In various non-limiting embodiments, the ion species 118 may have an ion energy between 500 eV and 7 keV, depending upon the material of the ion species 118 and the thickness of the dopant layer 116. This process is generally illustrated in FIG. 1E, representing an instance subsequent to the instance of FIG. 1D. At this instance, most or all of the dopant layer 116 may be absent from the surface 105. In addition, a doped layer 120 has been formed within the substrate base 104. The doped layer 120 may be formed by implantation of ion species 118 directly into the substrate base 104, as well as the driving of dopant material from the dopant layer 116 into the substrate base as a result of knock on collisions from the ion species 118, for example. In other words, an implant range for the ion species 118 may be greater than a thickness of the dopant layer 116 before the implant process, such that at least some ions of ion species 118 are implanted directly into the substrate base 104. As such, the doped layer 120 may represent a mixture of dopant from the dopant layer 116 and dopant from the ion species 118.

Note that according to various embodiments, the operations of FIGS. 1B-1E may be repeated in cyclical fashion to achieve a target dopant dose within a substrate. Said differently, the plasma clean, the deposition of the dopant layer, and the implant process may be performed as an implant cycle, where the implant cycle is repeated one or more times to implant a target dopant level into the substrate.

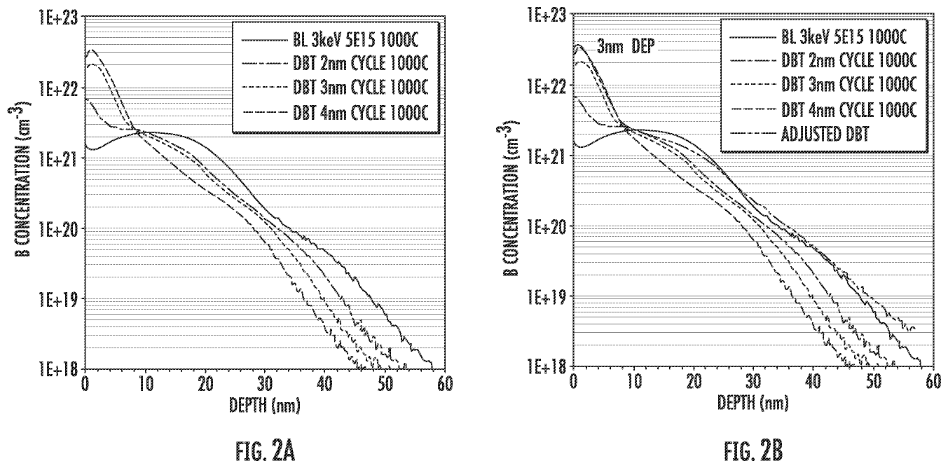

Turning to FIG. 2A there is shown an experimental example of a dopant profile for a semiconductor substrate that is processed according to embodiments of the disclosure, and in particular, according to the operations of FIGS. 1A-1E. FIG. 2A presents a graph that depicts boron concentration as a function of depth in a silicon substrate. As noted, the silicon substrate has been processed wherein a plasma clean of the silicon substrate, boron deposition and implantation process have been performed in sequence to introduce boron into the silicon substrate. FIG. 2A depicts a series of curves that use three different thicknesses of dopant layer 116—2 nm, 3 nm, and 4 nm, followed by ion implantation performed at 3 keV BF₂ and 5 E15/cm² ion dose and activation annealing at 1000° C. FIG. 2A also shows a control curve illustrating the boron dopant profile for and ion implantation process performed at 3 keV BF₂ and 5 E15/cm² ion dose, followed by activation annealing at 1000° C., without any dopant layer. The Note that in FIG. 2A, the outer surface of the silicon substrate is represented by the 0 depth along the X-axis. As shown, the boron concentration at a depth of 1 nm to 3 nm below the outer surface is very high, in the range of approximately 5 E21/cm³-5 E22/cm³. Moreover, within the thickness range of dopant layer 116 shown, the boron concentration near the substrate surface increases with increasing thickness, particularly between 2 nm thickness and 3 nm thickness. In contrast, the boron concentration near the substrate surface for the control sample is relatively lower, not exceeding 5 E21/cm³. In addition, the junction depth is shallower in samples having a dopant layer 116, as compared to the sample implanted without the dopant layer 116. Moreover, the junction depth decreases with increasing dopant layer thickness up to at least 4 nm.

FIG. 2B depicts the dopant profile for boron doping, for substrates processed according to the present embodiments, where an additional curve (‘adjusted’) is added to those curves depicted in FIG. 2A. In this example, a substrate having a 3 nm dopant layer 116 has been processed according to processes of FIGS. 1A to 1E. In this case, the adjusted curve represents processing conditions where the implant energy and dose of boron is adjusted so that the junction depth substantially matches that depth of the control sample. However, the surface concentration of boron dopant is much higher than the surface concentration of the control sample, demonstrating that the present embodiments provide a mechanism wherein the junction depth may be adjusted independent of the dopant concentration, especially dopant concentration near the surface, such as approximately 10 nm of the surface.

In other embodiments of the disclosure, the above approach of in-situ plasma cleaning, in-situ plasma deposition of a dopant layer, followed by ion implantation, may be employed for phosphorous, in order to provide better control of dopant concentration and junction depth.

In accordance with embodiments of the disclosure, the approach outlined with respect to FIGS. 1A-1E has been performed on device substrates, where various measurements have confirmed superior performance in comparison to devices implanted with dopant without the operations of FIGS. 1A-1C for example. Examples of improved properties include lower contact resistance in source/drain contacts formed over the doped substrate, improved ON current in a transistor device (I_{ON}), as well as reduce OFF current (I_{OFF}).

Without limitation as to any particular theory, the improved dopant engineering (better control of surface dopant concentration, better control of junction depth) achieved according to the present embodiments may result in part by the preservation of a semiconductor surface that has little of no native oxide disposed thereon. During an ion implantation process, many silicon interstitials are generated in the bulk of the semiconductor substrate being implanted. These silicon interstitials travel within the semiconductor substrate, even when substrate temperature is at room temperature. In the presence of native oxide, the interstitials may be reflected back, into the bulk of the semiconductor substrate, causing defectivity, deactivation, and enhanced dopant diffusion. The multi-process substrate treatment disclosed herein addresses this problem as follows. The plasma cleaning within an ion implantation apparatus results in removal of a native oxide from the surface of the semiconductor substrate, while the maintaining of the semiconductor substrate under high vacuum conditions will tend to preserve the semiconductor surface free of native oxide up to the time when dopant deposition is performed. This native-oxide-free surface may expose a rich layer of silicon dangling bonds, which condition will enable silicon interstitials to terminate at the surface. The result of this termination may include higher dopant activation, less defectivity, and less interstitial-enhanced diffusion of the dopant species. This reduction in dopant diffusion into the semiconductor substrate an higher activation may be further enhanced by the presence of the deposited layer of dopant on the surface during ion implantation of dopant species. During the knock-in process that occurs as a result of ion implantation, the surface concentration of dopant may be enhanced without causing undue increase in the depth of the dopant profile in the semiconductor substrate, and thus, a relatively lower junction depth. As best understood, this result is accomplished due to the entire series of processes, including plasma cleaning, dopant layer deposition, and ion implantation being completed on an integrated beamline architecture that maintains the substrate under common vacuum.

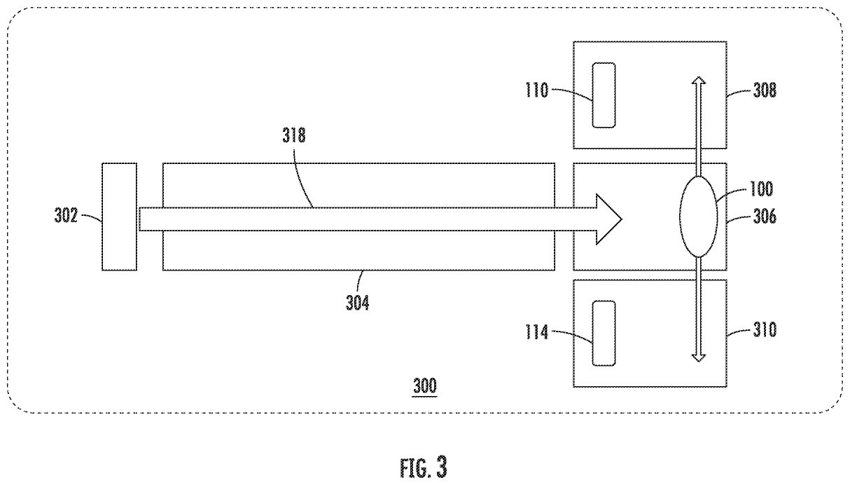

Turning to FIG. 3 there is depicted in block form the architecture of an exemplary ion implantation system, shown as ion implanter 300, according to embodiments of the disclosure. The ion implanter 300 includes an ion source 302 to generate ion beam 318 that implants the ion species 118, as described above. The ion implanter 300 may include various components to accelerate, decelerated, shape, and filter an ion beam, as known in the art. These components are depicted as beamline 304. Downstream of the beamline 304 an end station 306 is provided to house the substrate 110, during ion implantation. The ion implanter 300 may include a plasma clean chamber 308 as well as a plasma doping chamber 310. These chambers may be a single chamber or may be separate chambers that are communicatively coupled to the end station 306, so that the semiconductor substrate 100 may be transported between the different chambers, while being maintained under a vacuum environment to perform to processes as outlined in FIGS. 1A-1C. In other embodiments one or more of the plasma source 110 and the plasma source 114 may be included within the end station 306.

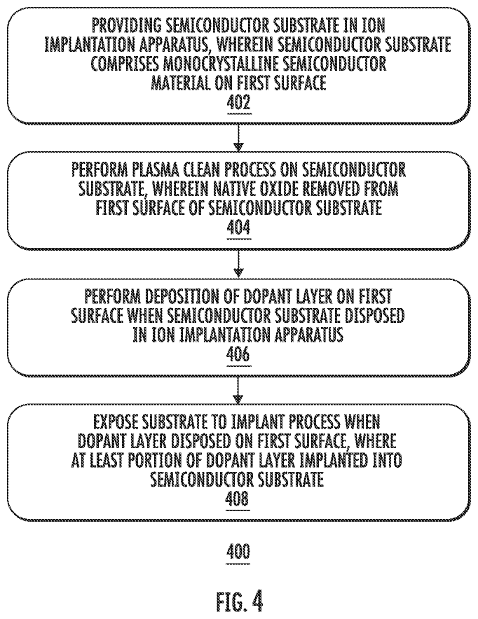

Turning now to FIG. 4, there is shown an exemplary process flow 400, according to embodiments of the disclosure. At block 402, the operation is performed of providing a semiconductor substrate in an ion implantation apparatus, where the semiconductor substrate comprises a monocrystalline semiconductor material on a first surface. It may be understood that the first surface may have a native oxide coating that extends up to several nanometers above the first surface. Thus, the first surface of the monocrystalline semiconductor material may be located a few nanometers below the outer surface of the semiconductor substrate at this instance.

At block 404, a plasma clean operation is performed on the semiconductor substrate, wherein the native oxide is removed from first surface of the semiconductor substrate. The plasma clean may be performed using a suitable species at a relatively lower energy, such as several eV up to several tens of eV. Examples of suitable species include hydrogen ions or hydrogen radicals, and related species. As such, the plasma clean may remove the native oxide without damaging the monocrystalline semiconductor material that extends to the first surface.

At block 406, a deposition of dopant layer is performed on the first surface when the semiconductor substrate is disposed in the ion implantation apparatus. The deposition of the dopant layer may be performed using a plasma source that provides relatively lower energy ion species or radical species, having energy less than 100 eV, for example. The dopant layer may have a suitable thickness such as 1 nm to 7 nm, or 2 nm to 4 nm, in accordance with some non-limiting embodiments.

At block 408, the substrate is exposed to an ion implant process when the dopant layer is disposed on the first surface of the semiconductor substrate. The implant process may involve ion species that are derived from a plasma source, where the ion energy may range up to 7 keV in some non-limiting embodiments. In this operation, at least a portion of the dopant layer may be implanted into semiconductor substrate. In other words, during the implant process the ion species may cause at least some atoms of the dopant layer to be driven into the semiconductor substrate that lies immediately subjacent the dopant layer.

In view of the above, the present embodiments convey the following advantages. A first advantage is, by performing a multiple process treatment for doping a substrate, a higher activation of a dopant may be achieved with less defectivity and less dopant diffusion. A second advantage is the dopant concentration may be enhanced while not impacting the depth of dopant profile, such as the junction depth.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, while the present disclosure has been described herein in the context of a particular implementation in a particular environment for a particular purpose, those of ordinary skill in the art will recognize the usefulness of the present embodiments is not limited thereto and the present embodiments may be beneficially implemented in any number of environments for any number of purposes. Thus, the claims set forth below are to be construed in view of the full breadth and spirit of the present disclosure as described herein.

What is claimed is:

1. A method of doping a semiconductor substrate, comprising:
exposing a substrate surface of the semiconductor substrate to a plasma clean;
performing a deposition of a dopant layer on the substrate surface using a plasma source, after the plasma clean, the dopant layer comprising a dopant element; and
exposing the semiconductor substrate to an implant process when the dopant layer is disposed on the substrate surface, wherein the implant process introduces an ion species comprising the dopant element into the substrate,
wherein the substrate is maintained under vacuum over a process duration spanning the plasma clean, the deposition of the dopant layer, and the implant process,
and wherein at least a portion of the dopant layer is implanted into the substrate during the implant process.

2. The method of claim 1, wherein the substrate surface includes a native oxide, before the plasma clean, and wherein the native oxide is removed after the plasma clean.

3. The method of claim 1, wherein the plasma clean is completed by:
generating a hydrogen species in a plasma chamber; and
directing the hydrogen species to the substrate surface when the substrate is at a cleaning temperature between room temperature and 100° C.,
wherein the substrate surface is terminated with a hydrogen passivation after the plasma clean.

4. The method of claim 1, wherein the performing the deposition comprises:
generating a dopant species in the plasma source, the dopant species comprising a dopant element; and
directing the dopant species to the substrate surface when the substrate is at a substrate temperature of between room temperature and −100° C.

5. The method of claim 4, wherein the dopant species comprises a boron-containing species or a phosphorous-containing species.

6. The method of claim 4, wherein the dopant species comprises an energy from several eV to 100 eV.

7. The method of claim 4, wherein the dopant layer comprises a thickness of 1 nm to 7 nm before the implant process.

8. The method of claim 1, wherein the dopant element is derived from a dopant species that comprises BF₃ or PF₃, and wherein the ion species comprises an ion energy of less than 7 keV.

9. The method of claim 7, wherein an implant range for the ion species is greater than a thickness of the dopant layer before the implant process.

10. The method of claim 1, wherein the plasma clean, the deposition of the dopant layer, and the implant process are performed as an implant cycle, wherein the implant cycle is repeated one or more times to implant a target dopant level into the semiconductor substrate.

11. A method of doping a substrate, comprising:
providing a monocrystalline semiconductor material on a surface of the substrate;
exposing the surface to a plasma clean, wherein a native oxide is removed from the surface;
performing a deposition of a dopant layer on the surface of the substrate using a plasma source, after the plasma clean, the dopant layer comprising a dopant element; and
exposing the substrate to an implant process when the dopant layer is disposed on the substrate surface, wherein the implant process introduces an ion species comprising the dopant element into the substrate,
wherein the substrate is maintained under vacuum over a process duration spanning the plasma clean, the deposition of the dopant layer, and the implant process,
and wherein at least a portion of the dopant layer is implanted into the substrate during the implant process.

12. The method of claim 11, wherein the plasma clean is completed by:
generating a hydrogen species in a plasma chamber; and
directing the hydrogen species to the surface of the substrate when the substrate is at a cleaning temperature between room temperature and −100° C., wherein the surface of the substrate is terminated with a hydrogen passivation after the plasma clean.

13. The method of claim 11, wherein the performing the deposition comprises:
generating a dopant species in the plasma source, the dopant species comprising a dopant element; and
directing the dopant species to the surface of the substrate when the substrate is at a substrate temperature of between room temperature and 100° C.

14. The method of claim 13, wherein the dopant species comprises an energy from several eV to 100 eV.

15. The method of claim 11, wherein the dopant layer comprises an thickness of 1 nm to 7 nm before the implant process, and wherein an implant range for the ion species is greater than a thickness of the dopant layer before the implant process.

16. A method of doping a semiconductor substrate, comprising:
providing the semiconductor substrate in a beamline ion implanter;
exposing a substrate surface of the semiconductor substrate to a plasma clean;
performing a deposition of a dopant layer on the substrate surface using a plasma source, after the plasma clean, the dopant layer comprising a dopant element; and
exposing the substrate to an implant process when the dopant layer is disposed on the substrate surface, wherein the implant process introduces an ion species comprising the dopant element into the semiconductor substrate,
wherein the substrate is maintained in the beamline ion implanter under vacuum over a process duration spanning the plasma clean, the deposition of the dopant layer, and the implant process,
and wherein at least a portion of the dopant layer is driven into the semiconductor substrate during the implant process.

17. The method of claim 16, wherein the substrate surface includes a native oxide, before the plasma clean, wherein the native oxide is removed after the plasma clean, and wherein the substrate surface is terminated with a hydrogen passivation after the plasma clean.

18. The method of claim 16, wherein the performing the deposition comprises:
generating a dopant species in the plasma source, the dopant species comprising a dopant element; and
directing the dopant species to the substrate surface when the semiconductor substrate is at a substrate temperature of between room temperature and 100° C.

19. The method of claim 16, wherein the dopant layer comprises an thickness of 1 nm to 7 nm before the implant process, and wherein an implant range for the ion species is greater than a thickness of the dopant layer before the implant process.

20. The method of claim 16, wherein the plasma clean, the deposition of the dopant layer, and the implant process are performed as an implant cycle, wherein the implant cycle is repeated one or more times to implant a target dopant level into the substrate.
